(19) United States
(12) Patent Application Publication
(10) Pub. No.: US 2004/0141291 A1
(43) Pub. Date: Jul. 22, 2004

(54) High-efficiency heat sink and method for manufacturing the same

(76) Inventor: Chao Ming Chen, Taipei (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/420,800

(22) Filed: Apr. 23, 2003

(30) Foreign Application Priority Data
Jan. 21, 2003 (TW) 092101183

(51) Int. Cl. H05K 7/20

(52) U.S. Cl. 361/704

(57) ABSTRACT

The present invention discloses a high-efficiency heat sink and a method for manufacturing the heat sink so as to achieve high efficiency in heat dissipation with low cost. The present invention is characterized in that die casting, forging or injection molding is used to form a thermal conductive core having a substrate and a plurality of thermal conductive fins, followed by the formation of a heat-dissipating case so as to form a body and a plurality of heat-dissipating fins covering the thermal conductive core. The thermal conductive core transmits the heat from a heat source (typically an electronic element in operation) to all over the heat sink that efficiently dissipates the heat through the heat-dissipating case into the air.

### BACKGROUND OF THE INVENTION

1. Field of the Invention

The present invention generally relates to a heat sink and a method for manufacturing the same and, more particularly, to a high-efficiency heat sink and a method characterized in that die casting or injection molding is used to form a thermal conductive core, followed by the formation of a heat-dissipating case covering the thermal conductive core. The thermal conductive core transmits the heat from a heat source (typically an electronic element in operation) to all over the heat sink that efficiently dissipates the heat through the heat-dissipating case into the air.

2. Description of the Prior Art

In recent years, with the rapid and unceasing development in semiconductor processing technology, the size of a transistor is reduced such that the number of transistors fabricated on a single chip is increased. Moreover, as the switching rate of the transistors goes higher, the heat generated from the chip increases. That is the reason why the industry has the so-called “10-degree rule”, indicating that the lifetime of the chip reduces to half for every 10-degree C. rise in operation temperature. Therefore, for a highly heat-generating semiconductor chip, the performance as well as the lifetime depends strongly on the ability in heat dissipation.

As a prior art, a heat sink formed of aluminum or an aluminum-containing alloy is attached onto the heat-generating device (such as a central process unit). It is a better solution when an electric fan is provided. However, aluminum has good ability in heat dissipation but poor in thermal conductivity, that limits its performance as a heat sink. Also, copper may be used as a heat sink because it has good ability in thermal conductivity; however, it suffers from poor heat dissipation. Moreover, other materials such as graphite may also be used to exhibit acceptable performance but the cost is too high.

Recently, there has provided a solution as shown in FIGS. 1A and 1B, in which a heat sink is characterized in that a body 12 with a plurality of fins 121 formed of a material with good ability in heat dissipation (such as aluminum) is milled by computer numerical control (CNC) to have a fillister 123 that accommodates a copper plate 14 embedded at the bottom. In this manner, the copper plate 14 comes into contact with a CPU 16 and delivers the heat generated by the CPU 16 into the body 12. The heat is then dissipated from the fins 121 into the air.

Accordingly, such a solution overcomes the afore-mentioned problems. However, precise CNC processing complicates the fabrication of the heat sink and gives rise to the cost. On the other hand, the thermal conductivity between two different materials may be adversely affected by the fine gap at the interface. Furthermore, the highly thermal conductive region is limited by the copper-contacted portion of the body 12. The heat, however, is delivered from the bottom portion of the fins 121 to the edge by aluminum that has poor thermal conductivity. Therefore, there are still a lot to do to improve the ability in heat dissipation of the heat sink.

Therefore, there is need in providing a high-efficiency heat sink and a method for manufacturing the same, so as to achieve high efficiency in heat dissipation with low cost.

### SUMMARY OF THE INVENTION

Accordingly, it is the primary object of the present invention to provide a high-efficiency heat sink, characterized in that a thermal conductive core is formed of a highly thermal conductive material, followed by the formation of a heat-dissipating case covering the thermal conductive core so as to efficiently conduct the heat and dissipate the heat through the heat-dissipating case into the air.

It is another object of the present invention to provide a high-efficiency heat sink, characterized in that a thermal conductive core comprises a body and a plurality of fins formed on the body so as to deliver the heat from the body into each of the fins.

It is still another object of the present invention to provide a method for manufacturing a high-efficiency heat sink, characterized in that forging, die casting or injection molding is used to form a thermal conductive core and a heat-dissipating case so as to form a heat sink of all shapes.

It is still another object of the present invention to provide a method for manufacturing a high-efficiency heat sink, characterized in that a thermal conductive core is formed, followed by the formation of a heat-dissipating case by die casting or injection molding such that the thermal conductive core and the heat-dissipating case are fused together at the interface to avoid a fine gap that hinders thermal conductance.

In order to achieve the foregoing objects, the present invention provides a high-efficiency heat sink, comprising: a thermal conductive core having a substrate and a plurality of thermal conductive fins fixedly attached onto a top surface of the substrate; and a heat-dissipating case covering the thermal conductive core so as to form a body and a plurality of heat-dissipating fins; wherein the substrate of the thermal conductive core contacts a heat-generating source and conducts heat that is then delivered through the thermal conductive fins and the heat-dissipating fins into the air.

The present invention provides a method for manufacturing a high-efficiency heat sink, comprising steps of: forming a thermal conductive core having a substrate and a plurality of thermal conductive fins by one selected from a group consisting of die-casting, forging and injection molding; and forming a heat-dissipating case by one selected from a group consisting of die-casting and injection molding so as to form a body and a plurality of heat-dissipating fins covering the thermal conductive core such that the thermal conductive core and the heat-dissipating case are fused together to avoid hindering thermal conductance and to improve heat dissipation.

Other and further features, advantages and benefits of the invention will become apparent in the following description taken in conjunction with the following drawings. It is to be understood that the foregoing general description and following detailed description are exemplary and explanatory but are not to be restrictive of the invention. The accompanying drawings are incorporated in and constitute a part of this application and, together with the description, serve to explain the principles of the invention in general terms. Like numerals refer to like parts throughout the disclosure.

### BRIEF DESCRIPTION OF THE DRAWINGS

The objects, spirits and advantages of the preferred embodiment of the present invention will be readily understood by the accompanying drawings and detailed descriptions, wherein:

FIG. 1A is a decomposing cross-sectional view showing a heat sink in accordance with the prior art;

FIG. 1B is a completed cross-sectional view showing a heat sink in accordance with the prior art;

FIG. 2 is a 3-D perspective view showing a heat sink in accordance with one embodiment of the present invention;

FIG. 3A is a cross-sectional view showing the heat sink of FIG. 2 along the line A-A;

FIG. 3B is a cross-sectional view showing the heat sink of FIG. 2 along the line B-B;

FIG. 3C is a bottom view showing the heat sink of FIG. 2; and

FIG. 4 is a 3-D perspective view showing a heat sink in accordance with another embodiment of the present invention.

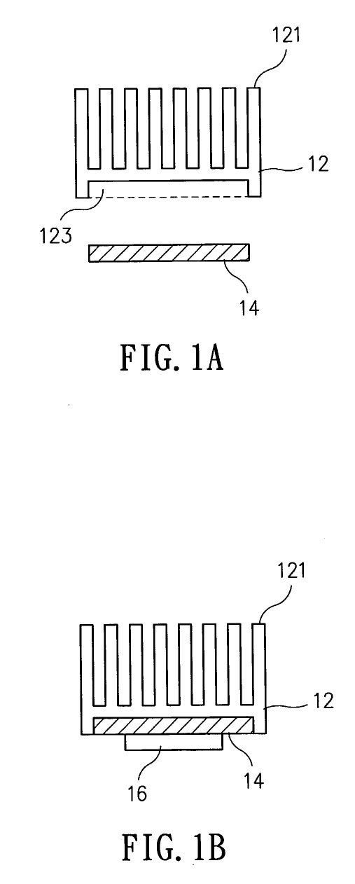

### DETAILED DESCRIPTION OF THE INVENTION

The present invention providing a high-efficiency heat sink and a method for manufacturing the same can be exemplified by the preferred embodiment as described hereinafter.

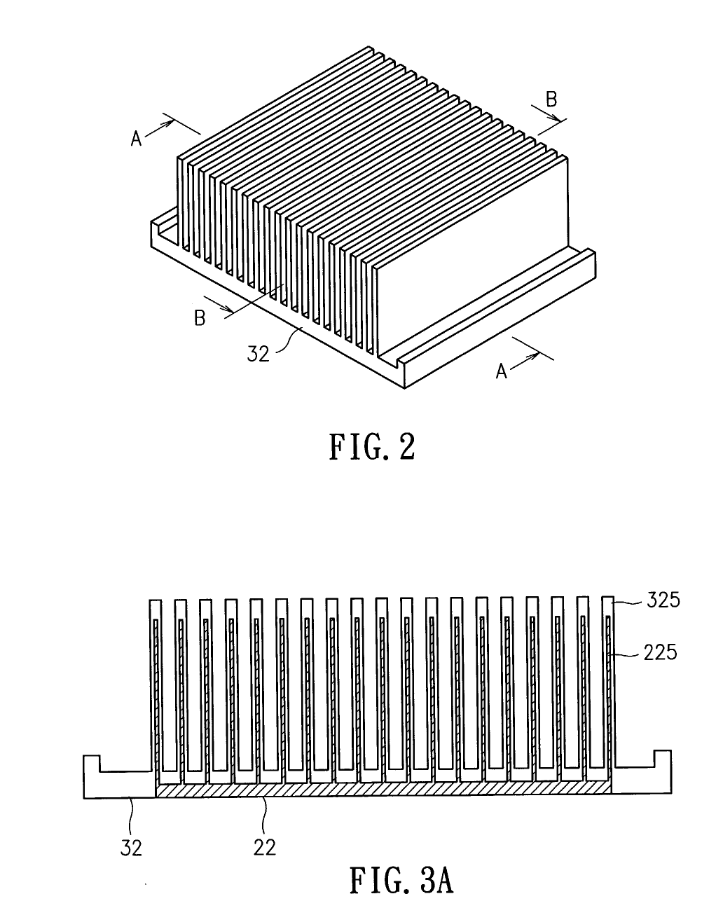

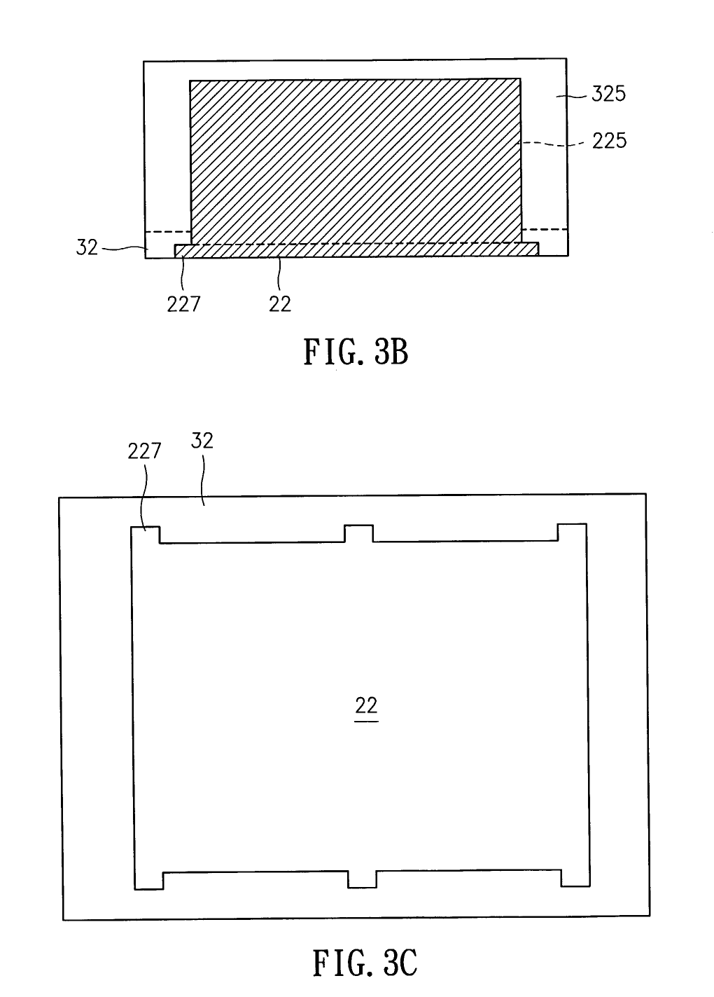

Please refer to FIG. 2 and FIGS. 3A to 3C, which represent a 3-D perspective view showing a heat sink in accordance with one embodiment of the present invention, a cross-sectional view along the line A-A, the line B-B, and a bottom view, respectively, showing the heat sink of FIG. 2.

As shown in the figures, the heat sink according to the present invention comprises: a thermal conductive core formed of a material with high thermal conductivity and a heat-dissipating case formed of a material with excellent heat dissipation. The thermal conductive core includes a substrate 22 and a plurality of thermal conductive fins 225 fixedly attached onto a top surface of the substrate 22. The heat-dissipating case covers the thermal conductive core so as to form a body 32 at the bottom portion and a plurality of heat-dissipating fins 325 of the heat sink. With a structure like this, the substrate 22 of the thermal conductive core contacts a heat-generating source (for example, a central process unit) and conducts heat that is then delivered through the thermal conductive fins 225 and the heat-dissipating fins 325 into the air. The performance can be further enhanced with the help from an electric fan.

Moreover, the thermal conductive core can be formed of a material with high thermal conductivity, such as copper, silver, gold and graphite; the heat-dissipating case can be formed of a material with excellent heat dissipation, such as aluminum and aluminum-containing alloys.

The heat sink in accordance with the present invention can be manufactured by using die-casting, injection molding or both. To begin with, die-casting or injection molding is employed to form the thermal conductive core. The thermal conductive core is later introduced into a mold for manufacturing a heat-dissipating case, and then die-casting or injection molding is employed again to form a heat-dissipating case with excellent heat dissipation to cover the thermal conductive core. Moreover, the thermal conductive core can also be formed by using forging.

The method for manufacturing the heat sink in accordance with the present invention preferably employs copper and aluminum for the thermal conductive core and the heat-dissipating case, respectively. The copper and aluminum are inexpensive relative to other materials. Since the melting point is 1083° C. for copper and 660° C. for aluminum, the thermal conductive core is firstly formed of copper and then the heat-dissipating case formed of aluminum. The thermal conductive core and the heat-dissipating case are fused together so as to avoid any possible fine gap that hinders thermal conductance.

Moreover, to position the thermal conductive core in the mold for the heat-dissipating case more precisely, a plurality of positioning pins 227 are provided on the peripheral of the substrate 22, as shown in FIG. 3C.

Alternatively, in the present invention, the heat-dissipating case can be firstly formed of aluminum or aluminum-containing alloys by using die-casting or injection molding. In other words, the body and the heat-dissipating fins attached onto the body are formed such that the body has a valley at the bottom and each of the heat-dissipating fins is hollow. The valley communicates with the hollow portion in each of the heat-dissipating fins. Later, melted copper is cast to fill in the valley and the hollow portion in each of the heat-dissipating fins so as to form a thermal conductive core having a substrate and a plurality of thermal conductive fins attached onto the substrate. Since the heat-dissipating case is placed in a low-temperature environment (such as water), the heat-dissipating case can remain its shape in spite of the 1083-° C. melted copper inside. Moreover, due to the high-temperature melted copper, the thermal conductive core (copper) and the heat-dissipating case (aluminum) are fused together so as to avoid any possible fine gap that hinders thermal conductance.

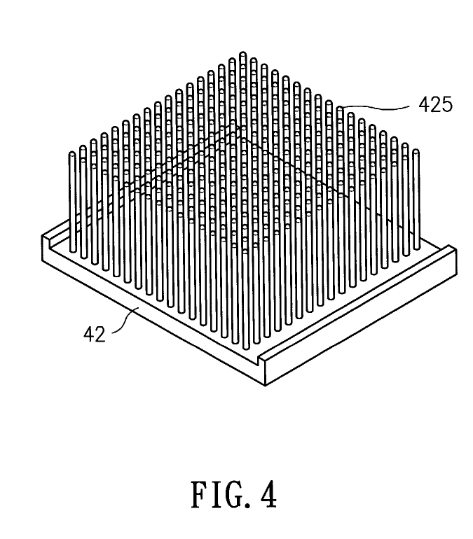

Though, we discuss the structure and the method for manufacturing the heat sink according to the present invention above in a most common shape of a heat sink. The invention can also be applied to heat sinks with various shape of exteriority, such as the heat sink shown in FIG. 4. The heat-dissipating case of the heat sink comprises a body 42 and a plurality of heat-dissipating pins 425 connected to the body 42. And there is also a thermal conductive core (not shown) contained in the interior of the heat sink for efficiently delivering the heat to whole the heat sink.

According to the above discussion, it is apparent that the present invention discloses a high-efficiency heat sink and a method for manufacturing the same so as to achieve high efficiency in hear dissipation with low cost. Therefore, the present invention has been examined to be novel, unobvious and useful.

Although this invention has been disclosed and illustrated with reference to a particular embodiment, the principles involved are susceptible for use in numerous other embodiments that will be apparent to persons skilled in the art. This invention is, therefore, to be limited only as indicated by the scope of the appended claims.

What is claimed is:

1. A high-efficiency heat sink, comprising:
a thermal conductive core, having a substrate at a bottom portion of said thermal conductive core and a plurality of thermal conductive fins attached onto a top surface of said substrate; and
a heat-dissipating case covering said thermal conductive core so as to form a body and a plurality of heat-dissipating fins;
wherein said substrate of said thermal conductive core contacts a heat-generating source and conducts heat.

2. The heat sink as recited in claim 1, wherein said thermal conductive core is formed of a material with high thermal conductivity.

3. The heat sink as recited in claim 1, wherein said heat-dissipating case is formed of a material with high heat-dissipating efficiency.

4. The heat sink as recited in claim 1, wherein said thermal conductive core is formed of copper.

5. The heat sink as recited in claim 1, wherein said heat-dissipating case is formed of a material selected from a group consisting of aluminum and aluminum-containing alloys.

6. The heat sink as recited in claim 4, wherein said thermal conductive core is formed by using one selected from a group consisting of die-casting, forging and injection molding.

7. The heat sink as recited in claim 5, wherein said heat-dissipating case is formed by using one selected from a group consisting of die-casting and injection molding.

8. The heat sink as recited in claim 1, further comprising a plurality of positioning pins provided on the peripheral of said substrate.

9. A method for manufacturing a heat sink, comprising steps of:
forming a thermal conductive core having a substrate and a plurality of thermal conductive fins; and
forming a heat-dissipating case so as to form a body and a plurality of heat-dissipating fins covering said thermal conductive core.

10. The method for manufacturing the heat sink as recited in claim 9, wherein said thermal conductive core is formed by using one selected from a group consisting of die-casting, forging and injection molding.

11. The method for manufacturing the heat sink as recited in claim 9, wherein said heat-dissipating case is formed by using one selected from a group consisting of die-casting and injection molding.

12. The method for manufacturing the heat sink as recited in claim 9, wherein said thermal conductive core is formed of copper.

13. The method for manufacturing the heat sink as recited in claim 9, wherein said heat-dissipating case is formed of a material selected from a group consisting of aluminum and aluminum-containing alloys.

14. The method for manufacturing the heat sink as recited in claim 9, wherein said heat sink further comprises a plurality of positioning pins provided on the peripheral of said substrate.

15. A method for manufacturing a heat sink, comprising steps of:
forming a heat-dissipating case so as to form a body and a plurality of heat-dissipating fins; wherein said body has a valley at the bottom, each of said heat-dissipating fins has a hollow portion and said valley communicates with said hollow portion in each of said heat-dissipating fins; and
forming a thermal conductive core having a substrate and a plurality of thermal conductive fins in said fillister and said hollow portion in each of said heat-dissipating fins, respectively.

16. The method for manufacturing the heat sink as recited in claim 15, wherein said heat-dissipating case is formed by using one selected from a group consisting of die-casting and injection molding.

17. The method for manufacturing the heat sink as recited in claim 15, wherein said thermal conductive core is formed by using casting.

18. The method for manufacturing the heat sink as recited in claim 15, wherein said thermal conductive core is formed of copper.

19. The method for manufacturing the heat sink as recited in claim 15, wherein said heat-dissipating case is formed of a material selected from a group consisting of aluminum and aluminum-containing alloys.
